(19) United States
(12) Patent Application Publication
(10) Pub. No.: US 2012/0305959 A1
(43) Pub. Date: Dec. 6, 2012

(54) LIGHT-EMITTING DIODE DEVICE AND METHOD FOR MANUFACTURING THE SAME

(75) Inventors: Kuo-Hui Yu, Tainan (TW); Chang-Hsin Chu, Tainan (TW); Chi-Lung Wu, Tainan (TW); Shin-Jia Chiou, Tainan (TW); Chung-Hsin Lin, Tainan (TW); Jui-Chun Chang, Tainan (TW)

(73) Assignee: CHI MEI LIGHTING TECHNOLOGY CORP., Tainan (TW)

(21) Appl. No.: 13/241,667

(22) Filed: Sep. 23, 2011

(30) Foreign Application Priority Data
May 31, 2011 (TW) 100119074

(51) Int. Cl. H01L 33/58; H01L 33/62

(52) U.S. Cl. 257/98; 438/22; 257/E33.073; 257/E33.066

(57) ABSTRACT

A light-emitting diode (LED) device, includes a substrate, having a first and a second surfaces, a first bonding layer, disposed on the first surface, a first epitaxial structure, having a third and a fourth surfaces and comprising a first and a second groove, wherein the first epitaxial structure comprises a second electrical type semiconductor layer, an active layer and a first electrical type semiconductor layer sequentially stacked on the first bonding layer, and the first groove extends from the fourth surface to the first electrical type semiconductor layer via the active layer, the second groove extends from the fourth surface to the third surface, a first electrical type conductive branch, a first electrical type electrode layer, an insulating layer, filled in the first and the second grooves, and a second electrical type electrode layer, electrically connected to the second electrical type semiconductor layer.

### CROSS-REFERENCE TO RELATED APPLICATION

This application claims priority of Taiwan Patent Application No. 100119074, filed on May 31, 2011, entitled “Light-Emitting Diode Device And Mathod For Manufacturing The Same” by Kuo-hui YU, Chang-Hsin CHU, Chi-Lung WU, Shin-Jia CHIOU, Chung-Hsin LIN, and Jui-Chun CHANG, the disclosure of which is incorporated herein by reference in its entirety.

### FIELD OF THE INVENTION

The present invention relates to a light-emitting device, and more particularly to a light-emitting diode (LED) device and method for manufacturing the same.

### BACKGROUND OF THE INVENTION

Referring to FIG. 1A and FIG. 1B, FIG. 1A is a schematic top view of a vertical LED structure in a related art and FIG. 1B is a schematic cross-sectional view taken along a cross-sectional line A-B in FIG. 1A. An LED structure 100 includes a substrate 102, a bonding layer 104, a p-type contact layer 106, a p-type semiconductor layer 108, an active layer 110, an n-type semiconductor layer 112, an n-type electrode pad 114, an n-type conductive branch 116 and a p-type electrode layer 118.

In the LED structure 100, the bonding layer 104, the p-type contact layer 106, the p-type semiconductor layer 108, the active layer 110 and the n-type semiconductor layer 112 are sequentially stacked on a surface 120 of the substrate 102. As shown in FIG. 1A, the n-type conductive branch 116 is connected to the n-type electrode pad 114, and extends to the outside from the n-type electrode pad 114. Moreover, as shown in FIG. 1B, the n-type electrode pad 114 and the n-type conductive branch 116 are both disposed on the n-type semiconductor layer 112. In addition, the p-type electrode layer 118 is disposed on the other surface 122 of the substrate 102 opposite to the surface 120. The p-type contact layer 106 normally is made of a high reflective material, so may also be referred to as a reflective layer.

However, the LED structure 100 has defects. Firstly, as the n-type electrode pad 114 and the n-type conductive branch 116 are both disposed on the n-type semiconductor layer 112 above the active layer 110, the n-type conductive branch 116 may absorb light emitted by the active layer 110 and thus lower light extraction efficiency of the LED structure 100.

Additionally, the vertical LED structure 100 is different from a horizontal LED structure in the prior art. FIG. 2 is a schematic cross-sectional view of a horizontal LED structure in the prior art. The horizontal LED structure 200 in the prior art includes a substrate 202; a non-doped GaN layer 204 disposed on the substrate 202; an n-type GaN layer 206 disposed on the non-doped GaN layer 204; an active layer 208 disposed on a part of the n-type GaN layer 206; a p-type GaN layer 210 disposed on the active layer 208; an n-type electrode pad 212 disposed on an exposed Ga-face 216 of the n-type GaN layer 206; a p-type ohmic contact layer 220 disposed on the p-type GaN layer 210; and a p-type electrode pad 214 disposed on a part of the p-type ohmic contact layer 220. Due to the characteristics of the material, a top surface of the n-type GaN layer 206 distant from the growth substrate is a Ga-face 216 and a bottom surface of the non-doped GaN layer 204 near the growth substrate is an N-face 218.

Therefore, in the horizontal LED structure 200, the n-type electrode pad 212 is disposed on the Ga-face 216 of the n-type GaN layer 206. Under this architecture, the n-type electrode pad 212 after annealing still maintains a good ohmic contact. On the other hand, in the vertical LED structure 100, the n-type electrode pad 114 and the n-type conductive branch 116 are disposed on the N-face of the n-type semiconductor layer 112. Therefore, when the n-type electrode pad 114 and the n-type conductive branch 116 are disposed on the N-face, the thermal stability of the n-type electrode pad 114 and the n-type conductive branch 116 is deteriorated. Hence, after the annealing process, the ohmic contact between the n-type electrode pad 114 and n-type conductive branch 116 and the n-type semiconductor layer 112 is deteriorated, thus causing the rising of the resistance between the n-type electrode pad 114 and n-type conductive branch 116 and the n-type semiconductor layer 112.

Additionally, in the process of the vertical LED structure 100, the p-type contact layer 106 needs to be subjected to the annealing process twice, that is the first annealing process after the p-type contact layer 106 is formed and the second annealing process after the n-type electrode pad 114 and the n-type conductive branch 116 are formed. Therefore, after the p-type contact layer 106 that also functions as a reflective layer subjected to the two annealing processes, the reflectivity is difficulty to control.

Therefore, a heretofore unaddressed need exists in the art to address the aforementioned deficiencies and inadequacies.

### SUMMARY OF THE INVENTION

In one aspect, the present invention relates to an LED device and a method for manufacturing the same, in which a conductive branch is disposed in an epitaxial structure, thus reducing the proportion of the light absorbed by the conductive branch.

In another aspect, the present invention relates to an LED device and a method for manufacturing the same, in which a first electrical type electrode pad and a first electrical type conductive branch are disposed on a Ga-face of a first electrical type semiconductor layer, thus improving a thermal stability of the first electrical type electrode pad and the first electrical type conductive branch.

In yet another aspect, the present invention relates to an LED device and a method for manufacturing the same, in which a second electrical type contact layer that also provides a reflective function is manufactured after an annealing process of the first electrical type electrode pad and the first electrical type conductive branch. Therefore, the reflectivity of the second electrical type contact layer can be effectively controlled.

In still another aspect, the present invention relates to an LED device and a method for manufacturing the same, in which an LED chip after cutting may be directly fixed on a package substrate or a conductive lead frame, and then a growth substrate is removed, and thus the fabricating of the LED device is substantially finished. Therefore, after the growth substrate is removed, the lithographic process may be omitted.

In an additional aspect, the present invention relates to an LED device and a method for manufacturing the same, in which after the LED chip after cutting is disposed on the package substrate or frame, an exhaust passage is not required to be additionally fabricated for ventilation of a gas generated in the process of removing the growth substrate by laser. Therefore, a light-emitting area utilization rate of the LED chip may be increased.

In a further aspect, the present invention relates to provide an LED device and a method for manufacturing the same, in which the LED chips having different light-emitting wavelengths may be successfully combined together by stacking, thus forming an LED device that provides blended light. Therefore, the diversity and applicability of the LED device may be improved.

According to the above objectives of the present invention, an LED device is provided. The LED device includes a substrate, a first bonding layer, a first epitaxial structure, a first electrical type conductive branch, a first electrical type electrode layer, an insulating layer and a second electrical type electrode layer. The substrate has a first surface and a second surface opposite to each other. The bonding layer is disposed on the first surface. The first epitaxial structure has a third surface and a fourth surface opposite to each other, and includes a first groove and a second groove. The first epitaxial structure includes a second electrical type semiconductor layer, an active layer and a first electrical type semiconductor layer sequentially stacked on the first bonding layer. The first groove extends from the fourth surface to the first electrical type semiconductor layer via the active layer, and the second groove extends from the fourth surface to the third surface. The first electrical type semiconductor layer and the second electrical type semiconductor layer have different electrical types. The first electrical type conductive branch is disposed on the first electrical type semiconductor layer in the first groove. The first electrical type electrode layer is disposed in the second groove, coplanar with the third surface, and connected to the first electrical type conductive branch. The insulating layer is filled in the first groove and the second groove. The second electrical type electrode layer and the second electrical type semiconductor layer are electrically connected.

According to an embodiment of the present invention, the second electrical type electrode layer is disposed on the second surface of the substrate, and the substrate is a conductive substrate.

According to another embodiment of the present invention, the first epitaxial structure further includes a third groove extending from the fourth surface to the third surface, and the insulating layer is further filled in the third groove. Moreover, the second electrical type electrode layer is disposed in the third groove and coplanar with the third surface. The LED device further includes a conductive layer electrically connected to the second electrical type electrode layer and the second electrical type semiconductor layer.

According to still another embodiment of the present invention, the LED device further includes a first conductive lead electrically connected to the first electrical type electrode layer and a first electrode of an external power supply and a second conductive lead electrically connected to the second electrical type electrode layer and a second electrode of the external power supply.

According to yet another embodiment of the present invention, the LED device further includes a second bonding layer disposed between the substrate and the first bonding layer, a first conductive lead electrically connected to the first electrical type electrode layer and a first electrode of an external power supply, and a second conductive lead electrically connected to the second bonding layer and a second electrode of the external power supply.

According to still another embodiment of the present invention, the LED device further includes a first transparent conductive layer, a second epitaxial structure, a plurality of first bonding pads, another first electrical type conductive branch, another first electrical type electrode layer, and another insulating layer. The first transparent conductive layer is disposed on the third surface. The second epitaxial structure has a fifth surface and a sixth surface opposite to each other, and includes a third groove and a fourth groove. The second epitaxial structure includes another second electrical type semiconductor layer, another active layer and another first electrical type semiconductor layer sequentially stacked on the first transparent conductive layer. The third groove extends from the sixth surface to the another first electrical type semiconductor layer via the another active layer, and the fourth groove extends from the sixth surface to the fifth surface. The first bonding pads are bonded between the first transparent conductive layer and the first epitaxial structure. The another first electrical type conductive branch is disposed on the another first electrical type semiconductor layer in the third groove. The another first electrical type electrode layer is disposed in the fourth groove, coplanar with the fifth surface, and connected to the another first electrical type conductive branch. The another insulating layer is filled in the third groove and the fourth groove.

According to still another embodiment of the present invention, the LED device further includes a second transparent conductive layer, a third epitaxial structure, a plurality of second bonding pads, still another first electrical type conductive branch, still another first electrical type electrode layer and still another insulating layer. The second transparent conductive layer is disposed on the fifth surface. The third epitaxial structure has a seventh surface and an eighth surface opposite to each other, and includes a fifth groove and a sixth groove. The third epitaxial structure includes still another second electrical type semiconductor layer, still another active layer and still another first electrical type semiconductor layer sequentially stacked on the second transparent conductive layer. The fifth groove extends from the eighth surface to the still another first electrical type semiconductor layer via the still another active layer, and the sixth groove extends from the eighth surface to the seventh surface. The second bonding pads are bonded between the second transparent conductive layer and the second epitaxial structure. The still another first electrical type conductive branch is disposed on still another first electrical type semiconductor layer in the fifth groove. The still another first electrical type electrode layer is disposed in the sixth groove, coplanar with the seventh surface, and connected to the still another first electrical type conductive branch. The still another insulating layer is filled in the fifth groove and the sixth groove.

According to the above objectives of the present invention, a method for manufacturing an LED device is also provided, which includes the following steps. A first epitaxial structure is formed on a first substrate. The first epitaxial structure includes a first electrical type semiconductor layer, an active layer and a second electrical type semiconductor layer sequentially stacked on the first substrate. The first epitaxial structure includes a first groove and a second groove. The first groove and the second groove extend from the second electrical type semiconductor layer respectively to the first electrical type semiconductor layer and the first substrate. A first electrical type conductive branch and a first electrical type electrode layer are respectively formed on the first electrical type semiconductor layer in the first groove and the first substrate in the second groove. An insulating layer is filled in the first groove and the second groove. A first bonding layer is formed on the second electrical type semiconductor layer and the insulating layer. A second substrate is bonded to the first bonding layer. The first substrate is removed.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The drawings described below are for illustration purposes only. The drawings are not intended to limit the scope of the present teachings in any way. The patent or application file may contain at least one drawing executed in color. If so, copies of this patent or patent application publication with color drawing(s) will be provided by the Office upon request and payment of the necessary fee.

Further features and benefits of the present invention will be apparent from a detailed description of preferred embodiments thereof taken in conjunction with the following drawings, wherein similar elements are referred to with similar reference numbers, and wherein:

FIG. 1A is a schematic top view of a vertical LED structure in a related art;

FIG. 1B is a schematic cross-sectional view taken along a cross-sectional line A-B in FIG. 1A;

FIG. 2 is a schematic cross-sectional view of a horizontal LED structure in a related art;

FIG. 3A is a top view of an LED device according to a first embodiment of the present invention;

FIG. 3B is a cross-sectional view taken along a cross-sectional line A-B in FIG. 3A;

FIG. 3C is a cross-sectional view taken along a cross-sectional line C-D in FIG. 3A;

FIG. 4A to FIG. 4E are cross-sectional views of processes of an LED device according to the first embodiment of the present invention;

FIG. 5A is a top view of an LED device according to a second embodiment of the present invention;

FIG. 5B is a cross-sectional view taken along a cross-sectional line E-F in FIG. 5A;

FIG. 6A to FIG. 6E are cross-sectional views of processes of an LED device according to the second embodiment of the present invention;

FIG. 7A and FIG. 7B are cross-sectional views of processes of an LED device according to a third embodiment of the present invention;

FIG. 8A and FIG. 8B are cross-sectional views of processes of an LED device according to a fourth embodiment of the present invention; and

FIG. 9A to FIG. 9E are cross-sectional views of processes of an LED device according to a fifth embodiment of the present invention.

### DETAILED DESCRIPTION OF THE INVENTION

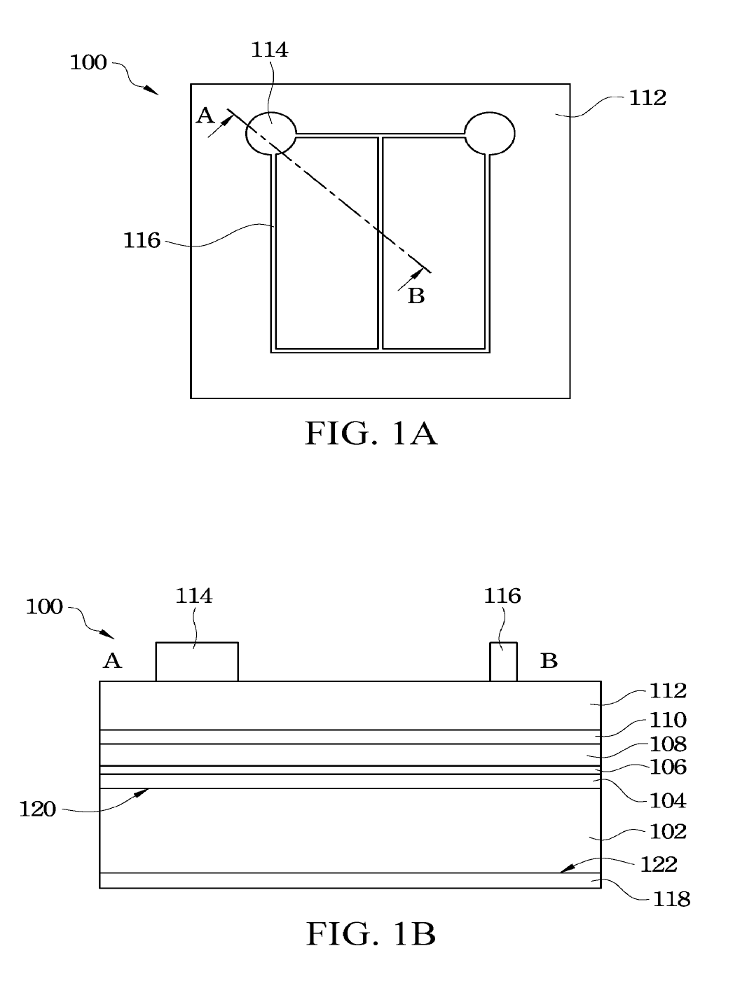

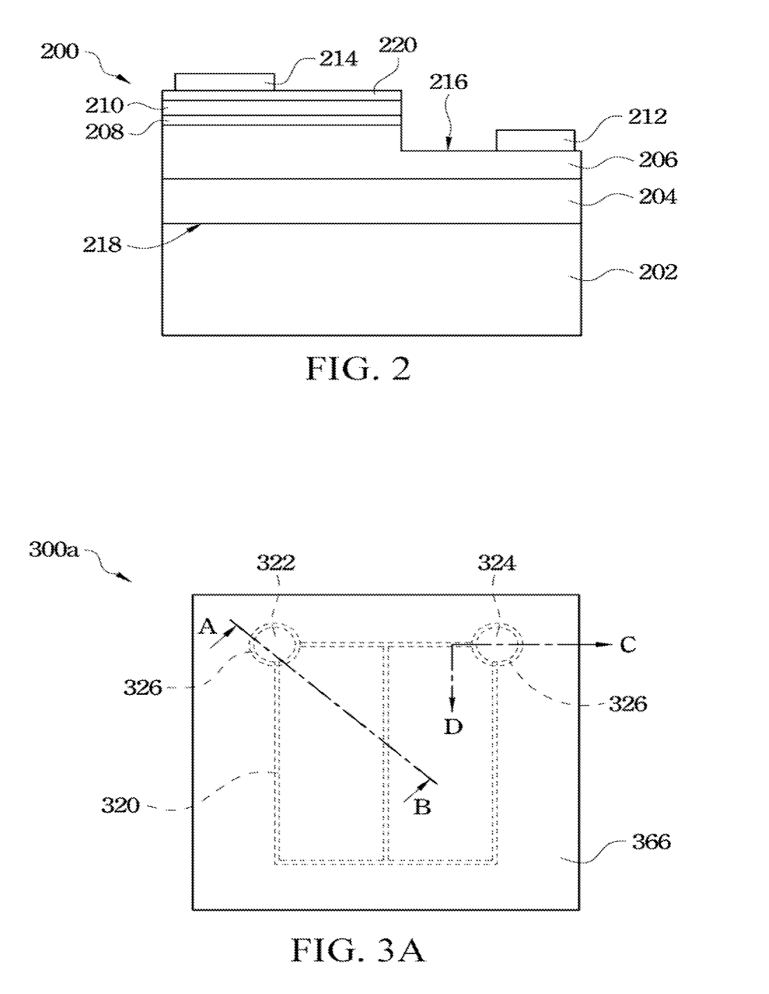

The present invention is more particularly described in the following examples that are intended as illustrative only since numerous modifications and variations therein will be apparent to those skilled in the art. Various embodiments of the invention are now described in detail. Referring to the drawings, FIGS. 1-9E, like numbers, if any, indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention. Additionally, some terms used in this specification are more specifically defined below.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

Unless otherwise defined, all technical and scientific terms used herein have the same meaning as commonly understood by one of ordinary skill in the art to which this invention pertains. In the case of conflict, the present document, including definitions will control.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, “plurality” means two or more.

As used herein, the terms “comprising,” “including,” “carrying,” “having,” “containing,” “involving,” and the like are to be understood to be open-ended, i.e., to mean including but not limited to.

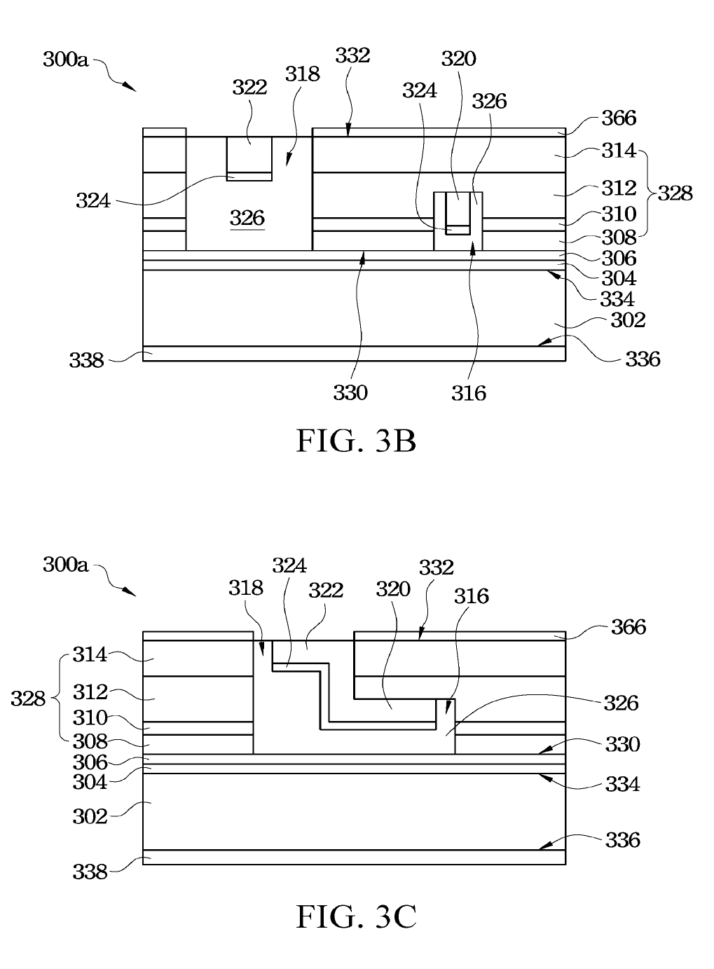

Referring to FIG. 3A to FIG. 3C, FIG. 3A is a top view of an LED device according to a first embodiment of the present invention, FIG. 3B is a cross-sectional view taken along a cross-sectional line A-B in FIG. 3A and FIG. 3C is a cross-sectional view taken along a cross-sectional line C-D in FIG. 3A. In this embodiment, an LED device 300a mainly includes a substrate 302, a bonding layer 304, an epitaxial structure 328, a first electrical type conductive branch 320, a first electrical type electrode layer 322, an insulating layer 326 and a second electrical type electrode layer 338, as shown in FIG. 3B.

In the LED device 300a, the substrate 302 has surfaces 334 and 336 respectively located on two opposite sides thereof. The epitaxial structure 328 is bonded to the surface 334 of the substrate 302 by the bonding layer 304, that is, the bonding layer 304 is bonded between the epitaxial structure 328 and the surface 334 of the substrate 302. The material of the bonding layer 304 is a conductive material, e.g. Au, AuSn or In. The material of the epitaxial structure 328 may be for example a GaN-based material. The epitaxial structure 328 has surfaces 330 and 332 located on two opposite sides thereof.

In one embodiment, the epitaxial structure 328 may include a second electrical type semiconductor layer 308, an active layer 310 and a first electrical type semiconductor layer 312 sequentially stacked above the bonding layer 304. Here, the surface 332 of the epitaxial structure 328 is the surface of the first electrical type semiconductor layer 312 and the surface 330 of the epitaxial structure 328 is the surface of the second electrical type semiconductor layer 308. In the present invention, the first electrical type and the second electrical type have different electrical types. For example, the first electrical type or the second electrical type is n-type and the other is p-type. In this embodiment, the first electrical type is n-type and the second electrical type is p-type.

In another embodiment, as shown in FIG. 3B, the epitaxial structure 328 may optionally include a non-doped semiconductor layer 314. The non-doped semiconductor layer 314 is disposed on the first electrical type semiconductor layer 312. Therefore, different from the above embodiment, the surface 332 of the epitaxial structure 328 here is the surface of the non-doped semiconductor layer 314. Moreover, the surface of the non-doped semiconductor layer 314 i.e. the surface 332 of the epitaxial structure 328 may be provided with a regularly arranged structure or an irregularly arranged structure, thus improving the light extraction rate of the LED device 300a.

In this embodiment, in accordance with the product requirements, the LED device 300a includes a second electrical type contact layer 306. The second electrical type contact layer 306 is disposed between the second electrical type semiconductor layer 308 and the bonding layer 304 to improve the electrical contact quality of the second electrical type semiconductor layer 308. Therefore, the material of the second electrical type contact layer 306 is the conductive material, e.g. Ni/Ag. In an example, the second electrical type contact layer 306 may also have a reflecting function, so the second electrical type contact layer 306 sometimes may be referred to as a reflective layer.

In this embodiment, the epitaxial structure 328 includes two grooves 316 and 318. The groove 316 extends from the second electrical type semiconductor layer 308 to the first electrical type semiconductor layer 312, that is, the groove 316 extends from the surface 330 of the epitaxial structure 328 to the first electrical type semiconductor layer 312 via the active layer 310. The bottom of the groove 316 exposes a part of the first electrical type semiconductor layer 312. On the other hand, the groove 318 extends from the second electrical type semiconductor layer 308 to the non-doped semiconductor layer 314, and penetrates the epitaxial structure 328, that is the groove 318 extends from the surface 330 of the epitaxial structure 328 to the surface 332.

Referring to FIG. 3B again, the first electrical type electrode layer 322 is disposed in the groove 318 and coplanar with the surface 332 of the epitaxial structure 328. In addition, the first electrical type conductive branch 320 is disposed on the first electrical type semiconductor layer 312 exposed by the groove 316 of the epitaxial structure 328. Referring to FIG. 3A and FIG. 3C at the same time, the first electrical type electrode layer 322 is connected to the first electrical type conductive branch 320, and the first electrical type conductive branch 320 may extend to the outside from the first electrical type electrode layer 322. The first electrical type conductive branch 320 and first electrical type electrode layer 322 are of an integrated structure. As shown in FIG. 3C, the first electrical type electrode layer 322 and the first electrical type conductive branch 320 have height differences. The material of the first electrical type conductive branch 320 and the first electrical type electrode layer 322 may be for example Ti/Al, Cr/Pt/Au, or Ti/Al/Ti/Au.

In one embodiment, the LED device 300a may optionally include a reflective layer 324. As shown in FIG. 3B and FIG. 3C, the reflective layer 324 is disposed on the top surface of the first electrical type electrode layer 322 and the first electrical type conductive branch 320. In another embodiment, the reflective layer 324 may be overlapped on the top surface and the side surfaces of the first electrical type electrode layer 322 and first electrical type conductive branch 320. The reflective layer 324 may be formed by for example Al, Ag, Pt or a distributed Bragg reflector (DBR) structure.

The insulating layer 326 is filled in the grooves 316 and 318 and overlaps the first electrical type conductive branch 320 and the first electrical type electrode layer 322 respectively located in the grooves 316 and 318. The material of the insulating layer 326 may be for example Spin-on-Glass (SOG), SiO₂ or SiN.

In this embodiment, as shown in FIG. 3B and FIG. 3C, the second electrical type electrode layer 338 is disposed on the surface 336 of the substrate 302. Here, the substrate 302 is preferably a conductive substrate, so that the second electrical type electrode layer 338 may be electrically connected to the second electrical type semiconductor layer 308 through the substrate 302, the bonding layer 304 and the second electrical type contact layer 306. In one embodiment, the substrate 302 may be a highly thermally conductive material, e.g. Si, Cu and CuW, thus improving the heat dissipation capability of the LED device 300a. The second electrical type electrode layer 338 may be formed by for example a Ti/Au structure. Definitely, if the substrate 302 is a conductive substrate and the substrate 302 and the follow-up processes may have good electrical characteristics, the second electrical type electrode layer 338 may be omitted optionally.

In another embodiment, the LED device 300a further optionally includes a light enhancement layer 366 according to the product requirements. The light enhancement layer 366 is disposed on the non-doped semiconductor layer 314. The light enhancement layer 366 may be a structure formed by a single material layer or a structure formed by stacking multiple material layers. In an example, a surface of one side of the light enhancement layer 366 opposite to the non-doped semiconductor layer 314 may have the regularly arranged structure or the irregularly arranged structure to improve the light extraction rate of the LED device 300a.

The material of the light enhancement layer 366 is preferably a transparent material, e.g. Al₂O₃, SiO₂, SiN or TiO₂. The refractive index of the light enhancement layer 366 is greater than the refractive index of air but is smaller than the refractive index of the non-doped semiconductor layer 314. Hence, the refractive indices of the epitaxial structure 328, the light enhancement layer 366 and the air have the same trend, that is, the refractive indices of the epitaxial structure 328, the light enhancement layer 366 and the air decrease in the same trend. With the same-trend design of the refractive indices, total reflection of the light emitted to the outside by the epitaxial structure 328 through light enhancement layer 366 is prevented, thus improving the light extraction rate of the LED device 300a.

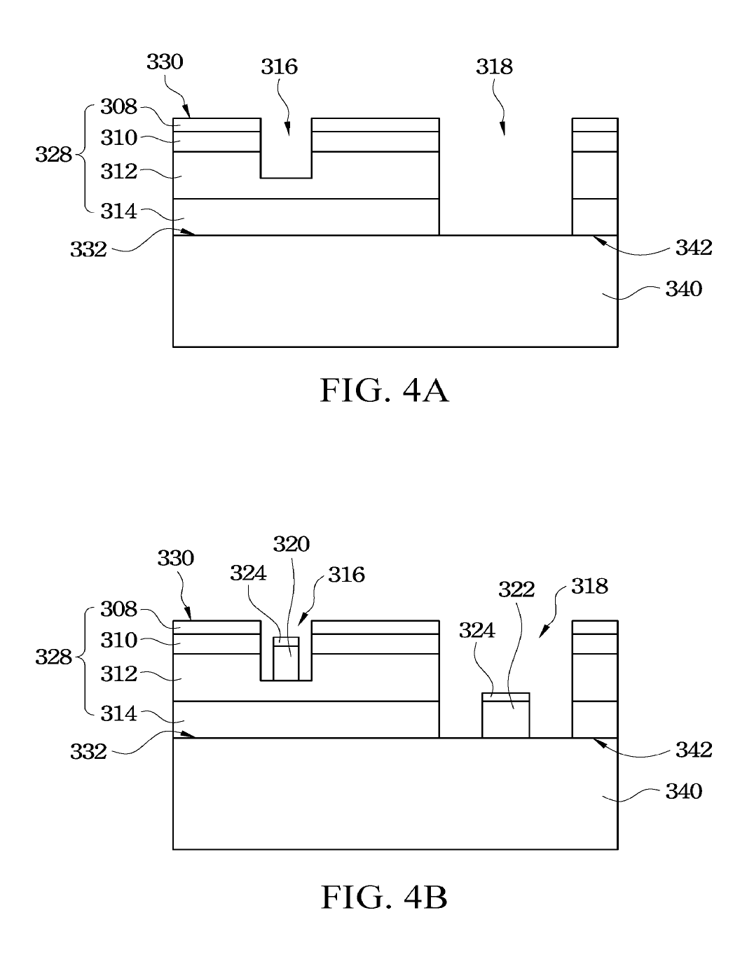

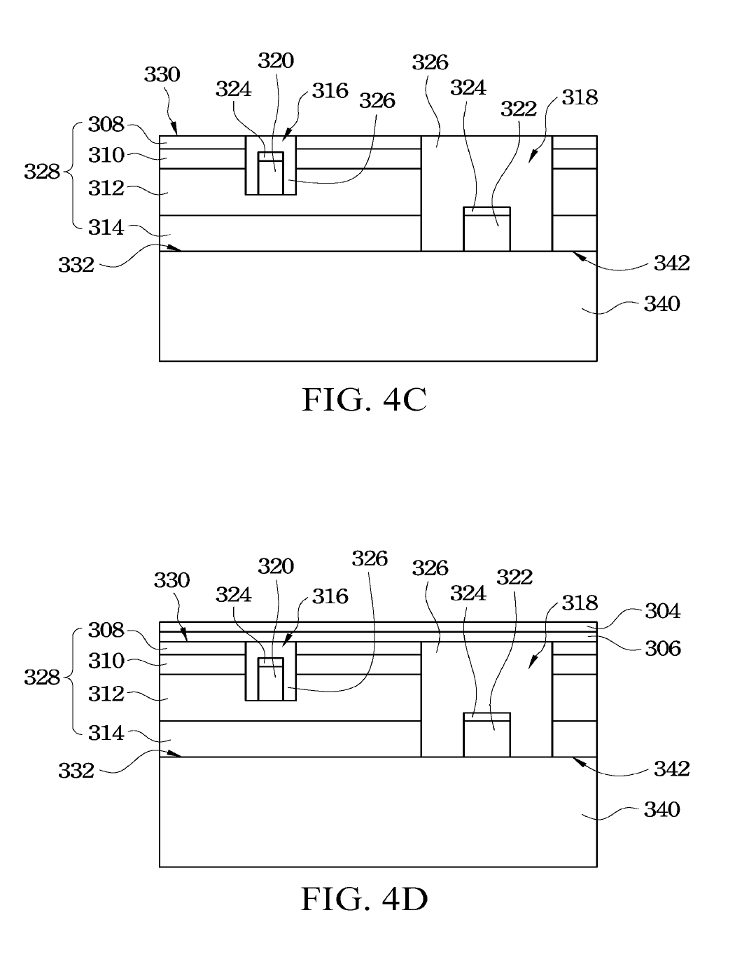

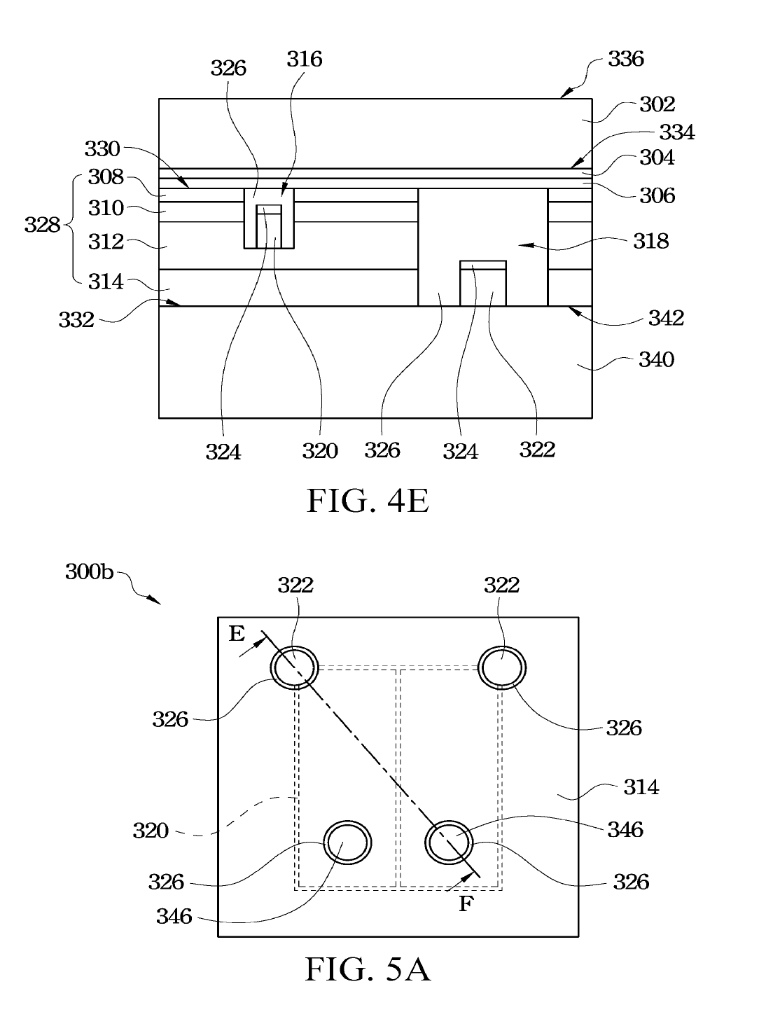

FIG. 4A to FIG. 4E are cross-sectional views of processes of an LED device according to the first embodiment of the present invention. In this embodiment, when the LED device 300a is fabricated, the substrate 340 is provided. The substrate 340 is an epitaxial substrate for growing an epitaxial structure 328. Then, a Metal-organic Chemical Vapor Deposition (MOCVD) process is employed to sequentially grow the non-doped semiconductor layer 314, the first electrical type semiconductor layer 312, the active layer 310 and the second electrical type semiconductor layer 308 of the epitaxial structure 328 on the surface 342 of the substrate 340.

Then, as shown in FIG. 4A, for example, a lithographic and etching process is employed to remove a part of the epitaxial structure 328, so as to define the grooves 316 and 318 in the epitaxial structure 328. The bottom of the groove 316 exposes the first electrical type semiconductor layer 312, the groove 318 penetrates the epitaxial structure 328, and the bottom of the groove 318 exposes the surface 342 of the substrate 340.

Then, as shown in FIG. 4B, for example, an evaporation, lithographic and etching process is employed to respectively form the first electrical type electrode layer 322 and the first electrical type conductive branch 320 in the grooves 318 and 316. The first electrical type electrode layer 322 is located on the exposed part of the surface 342 of the substrate 340 in the groove 318, and the first electrical type conductive branch 320 is located on the exposed part of the first electrical type semiconductor layer 312 in the groove 316. In one embodiment, after the first electrical type conductive branch 320 and the first electrical type electrode layer 322 are formed, an annealing process may be performed to improve the electrical contact resistance between the first electrical type conductive branch 320 and the contacted first electrical type semiconductor layer 312.

Afterwards, a deposition process is employed to form the reflective layer 324 covering the top surfaces of the first electrical type electrode layer 322 and the first electrical type conductive branch 320, as shown in FIG. 4B. Or, the reflective layer 324 may overlap the first electrical type electrode layer 322 and the first electrical type conductive branch 320.

Then, a deposition or spin-coating process may be employed to form an insulating material layer covering the entire surface 330 of the epitaxial structure 328 and filling up the grooves 316 and 318. Then, an etching or grinding process is employed to remove the extra insulating material on the surface 330 of the epitaxial structure 328 and form the insulating layer 326 filled in the grooves 316 and 318, as shown in FIG. 4C.

In one embodiment, a stop layer (not shown) e.g. an etching stop layer or a grinding stop layer may be firstly formed to cover the surface 330 of the epitaxial structure 328. For instance, when a dry etching process is employed to remove the extra insulating material on the epitaxial structure 328, a dry etching stop layer formed of Au or Ni material may be firstly formed on the surface 330 of the epitaxial structure 328.

Therefore, the following process of etching the insulating material may achieve a good control of the etching depth, and thus the formed surface of the insulating layer 326 and the surface 330 of the epitaxial structure 328 may be located on the same plane.

Then, for example, a deposition process is optionally employed to form a second electrical type contact layer 306 covering the surface 330 of the epitaxial structure 328 and the insulating layer 326. In one embodiment, after the second electrical type contact layer 306 is formed, the annealing process may be performed to improve the electrical contact resistance between the second electrical type contact layer 306 and the contacted second electrical type semiconductor layer 308. Then, for example, the deposition process is employed to form the bonding layer 304 covering the second electrical type contact layer 306 above the second electrical type semiconductor layer 308 and the insulating layer 326, thus forming the structure as shown in FIG. 4D. Then, as shown in FIG. 4E, the bonding layer 304 is employed to bond the epitaxial structure 328 and another substrate 302. Here, the substrate 302 is bonded to the bonding layer 304.

Afterwards, with the substrate 302 serving as the support structure, a laser lift-off or grinding process is employed to remove the growth substrate 340 used in epitaxy, thus exposing the surface 332 of the epitaxial structure 328, the first electrical type electrode layer 322 and the insulating layer 326. In this embodiment, an evaporation or sputtering process is employed to form the second electrical type electrode layer 338 covering the surface 336 of the substrate 302, thus substantially finishing the fabrication of the LED device 300a, as shown in FIG. 3B and FIG. 3C.

In the LED device 300a, the second electrical type electrode layer 338 and the bonding layer 304 are respectively located on surfaces 336 and 334 of two opposite sides of the substrate 302. Moreover, the substrate 302 may be a conductive substrate, and thus the second electrical type electrode layer 338 is electrically connected to the second electrical type semiconductor layer 308 via the substrate 302, the bonding layer 304 and the second electrical type contact layer 306.

In one embodiment, after the substrate 340 for epitaxial growth is removed, a deposition process is further employed to optionally form the light enhancement layer 366 covering the surface 332 of the epitaxial structure 328, that is, covering the non-doped semiconductor layer 314.

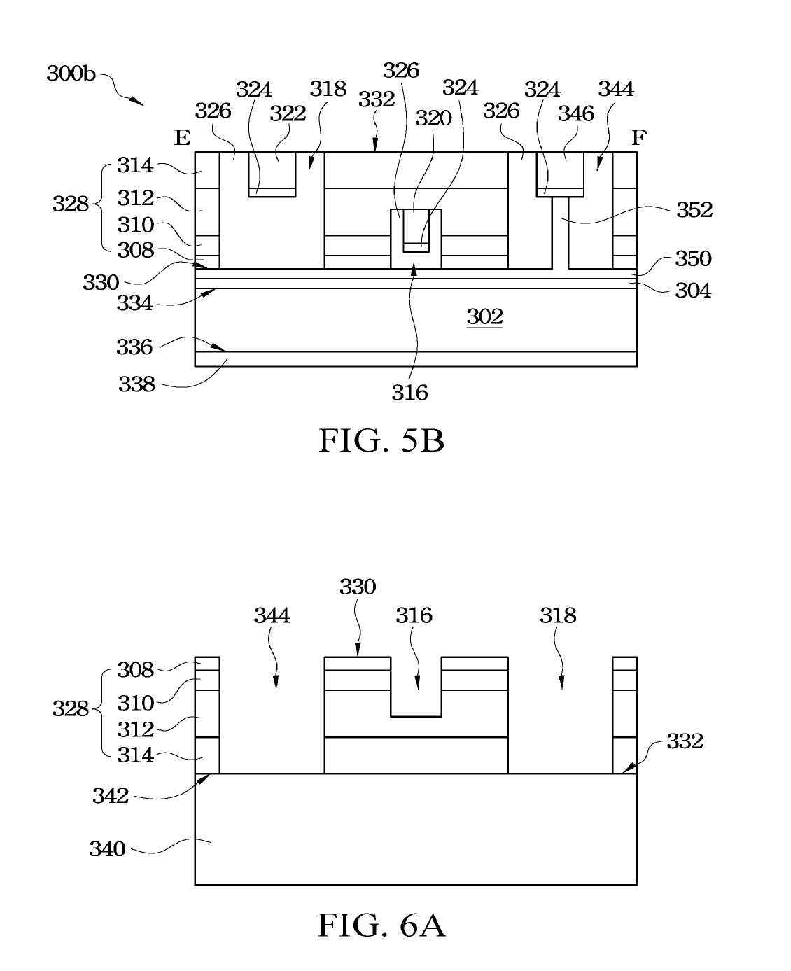

In the present invention, the first electrical type electrode layer and the second electrical type electrode layer may be located on the same plane. Referring to FIG. 5A and FIG. 5B, FIG. 5A is a top view of an LED device according to a second embodiment of the present invention and FIG. 5B is a cross-sectional view taken along a cross-sectional line E-F in FIG. 5A. In this embodiment, the architecture of an LED device 300b is substantially the same as that of the LED device 300a of the above embodiment, and the difference lies in that the epitaxial structure 328 of the LED device 300b further includes another groove 344 penetrating the epitaxial structure 328, as shown in FIG. 5B. Secondly, the second electrical type electrode layer 346 of the LED device 300b is located in the groove 344, and the second electrical type electrode layer 346 is electrically connected to the second electrical type semiconductor layer 308 through the conductive layer 350. Additionally, the second electrical type electrode layer 346 and the first electrical type electrode layer 322 are located on the same plane, as shown in FIG. 5A. That is to say, the second electrical type electrode layer 346 and the first electrical type electrode layer 322 are both coplanar with the surface 332 of the epitaxial structure 328, as shown in FIG. 5B.

It should be noted that in this embodiment, the fabrication of the light enhancement layer 366 of the LED device 300a is omitted. Definitely, according to the product requirement, like the LED device 300a in the first embodiment, a light enhancement layer may be added in the LED device 300b of this embodiment.

Referring to FIG. 5B again, in the LED device 300b, same as the groove 318, the groove 344 extends from the second electrical type semiconductor layer 308 to the non-doped semiconductor layer 314 and penetrates the epitaxial structure 328, that is, the groove 344 extends from the surface 330 of the epitaxial structure 328 to the surface 332. Likewise, the first electrical type electrode layer 322 is disposed in the groove 318 and coplanar with the surface 332 of the epitaxial structure 328. The first electrical type conductive branch 320 is disposed on the first electrical type semiconductor layer 312 exposed by the groove 316 of the epitaxial structure 328. On the other hand, the second electrical type electrode layer 346 is disposed in the groove 344. The first electrical type electrode layer 322 and the second electrical type electrode layer 346 are both coplanar with the surface 332 of the epitaxial structure 328. The second electrical type electrode layer 346 may be formed by for example a Ti/Au structure.

Likewise, the LED device 300b may optionally include a reflective layer 324. The reflective layer 324 is disposed on the top surfaces of the first electrical type electrode layer 322, the first electrical type conductive branch 320 and the second electrical type electrode layer 346. In another embodiment, the reflective layer 324 may overlap the top surfaces and side surfaces of the first electrical type electrode layer 322, the first electrical type conductive branch 320 and the second electrical type electrode layer 346. Moreover, the insulating layer 326 is filled in the grooves 316, 318 and 344 of the epitaxial structure 328 and overlaps the first electrical type conductive branch 320, the first electrical type electrode layer 322 and the second electrical type electrode layer 346 in the grooves 316, 318 and 344.

In this embodiment, the LED device 300b further includes a conductive layer 350 covering the surface 330 of the epitaxial structure 328. The conductive layer 350 has a conductive plug 352 extending and inserted in the insulating layer 326 in the groove 344, and the conductive layer 350 is connected to the second electrical type semiconductor layer 308 and the reflective layer 324 on the second electrical type electrode layer 346, so as to be electrically connected to the second electrical type electrode layer 346 and the second electrical type semiconductor layer 308.

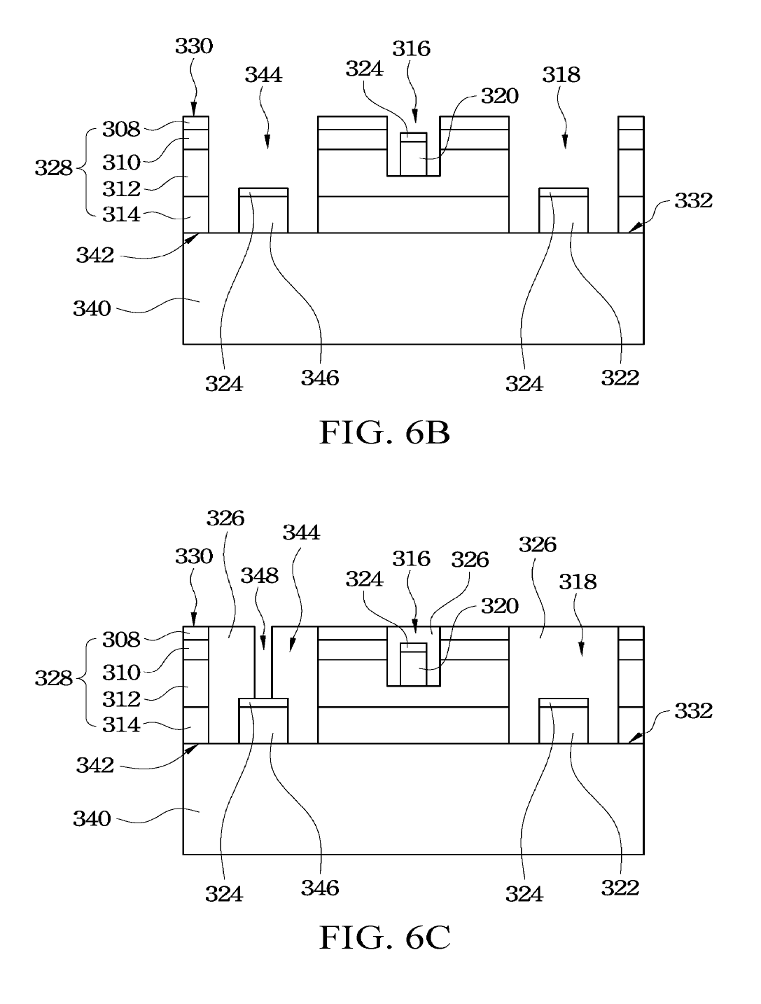

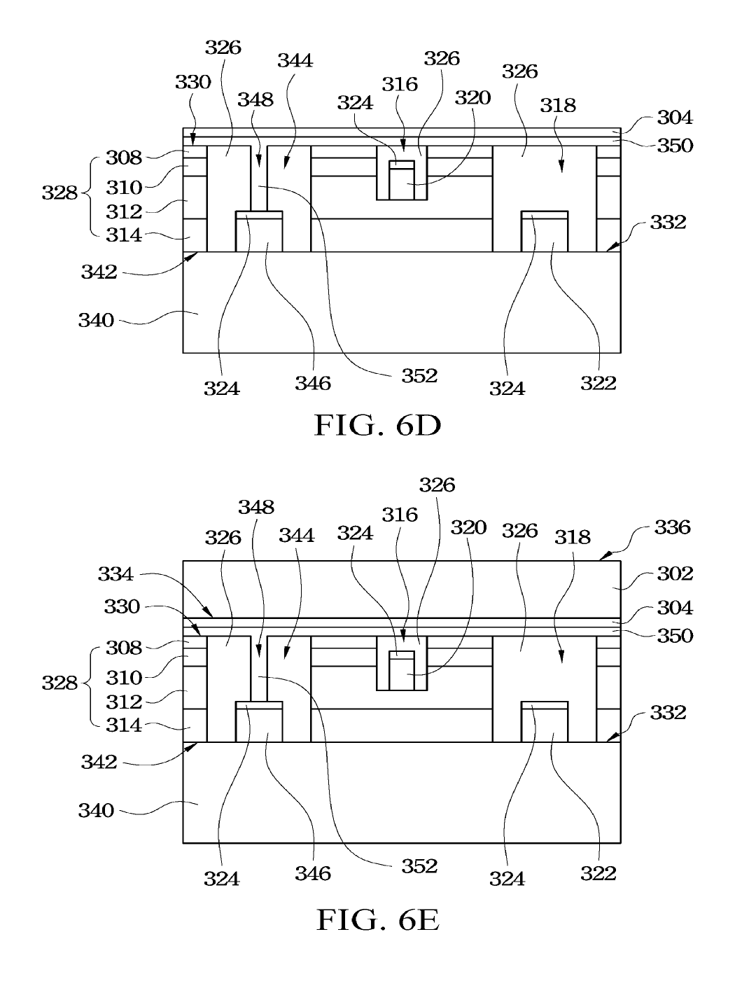

FIG. 6A to FIG. 6E are cross-sectional views of processes of an LED device according to the second embodiment of the present invention. In this embodiment, when the LED device 300b is fabricated, a substrate 340 is provided for the epitaxial structure 328 to be epitaxially grown thereon. Then, for example, a MOCVD process is employed to sequentially grow the non-doped semiconductor layer 314, the first electrical type semiconductor layer 312, the active layer 310 and the second electrical type semiconductor layer 308 of the epitaxial structure 328 on the surface 342 of the substrate 340.

Then, as shown in FIG. 6A, for example a lithographic and etching process is employed to remove a part of the epitaxial structure 328 so as to define the grooves 316, 318 and 344 in the epitaxial structure 328. The bottom of the groove 316 exposes the first electrical type semiconductor layer 312. The groove 318 penetrates the epitaxial structure 328, and the bottom of the groove 318 exposes the surface 342 of the substrate 340. Moreover, the groove 344 also penetrates the epitaxial structure 328, and the bottom of the groove 344 also exposes the surface 342 of the substrate 340.

Then, as shown in FIG. 6B, for example an evaporation process is employed to respectively form the first electrical type electrode layer 322, the first electrical type conductive branch 320 and the second electrical type electrode layer 346 in the grooves 318, 316 and 344. The first electrical type electrode layer 322 and the second electrical type electrode layer 346 are respectively located on the exposed part of the surface 342 of the substrate 340 in the grooves 318 and 344, and the first electrical type conductive branch 320 is located on the exposed part of the first electrical type semiconductor layer 312 in the groove 316. In one embodiment, after the first electrical type conductive branch 320, the first electrical type electrode layer 322 and the second electrical type electrode layer 346 are formed, an annealing process is performed to improve the electrical contact resistance between the first electrical type conductive branch 320 and the contacted first electrical type semiconductor layer 312.

After that, as shown in FIG. 6B, for example, a deposition process is employed to form the reflective layer 324 covering the top surfaces of the first electrical type electrode layer 322, the first electrical type conductive branch 320 and the second electrical type electrode layer 346. Or, the reflective layer 324 may overlap the first electrical type electrode layer 322, the first electrical type conductive branch 320 and the second electrical type electrode layer 346.

Then, for example, a deposition or spin-coating process is employed to form an insulating material layer covering the entire surface 330 of the epitaxial structure 328 and filling up the grooves 316 and 318. Afterwards, for example, an etching or grinding process is employed to remove the extra insulating material on the surface 330 of the epitaxial structure 328 and form the insulating layer 326 filled in grooves 316, 318 and 344. Then, for example a lithographic and etching technique is employed to define patterns of the insulating layer 326 in the groove 344 to remove a part of the insulating layer 326 in the groove 344, thereby forming an opening 348 in the insulating layer 326 in the groove 344. As shown in FIG. 6C, the bottom of the opening 348 exposes a part of the reflective layer 324 above the second electrical type electrode layer 346.

In one embodiment, likewise, a stop layer (not shown) e.g. an etching stop layer or a grinding stop layer may be firstly formed to cover the surface 330 of the epitaxial structure 328, and thus the following process of the etching or grinding the insulating material may achieve a good control of the removing depth, and thus the formed surface of the insulating layer 326 and the surface 330 of the epitaxial structure 328 may be located on the same plane.

Then, the conductive layer 350 covering the surface 330 of the epitaxial structure 328 and the insulating layer 326 and filling up the opening 348 in the insulating layer 326 in the groove 344 may be formed by using, for example, a deposition process, so as to be electrically connected to the second electrical type semiconductor layer 308 and the second electrical type electrode layer 346 below the reflective layer 324. The part of the conductive layer 350 in the opening 348 forms the conductive plug 352. In this embodiment, the conductive layer 350 is preferably made of a material that may form a good electrical contact with the second electrical type semiconductor layer 308.

In one embodiment, after the conductive layer 350 is formed, an annealing process is performed to improve the electrical contact resistance between the conductive layer 350 and the contacted second electrical type semiconductor layer 308. Then, as shown in FIG. 6D, for example, a deposition process is employed to form the bonding layer 304 covering the conductive layer 350 above the second electrical type semiconductor layer 308 and the insulating layer 326. Afterwards, as shown in FIG. 6E, a bonding layer 304 is employed to bond the epitaxial structure 328 and another substrate 302, so as to bond the epitaxial structure 328 to the substrate 302.

Then, the substrate 302 is used as the support structure, and for example a laser lift-off or grinding process is employed to remove the growth substrate 340 used in epitaxy, thus exposing the surface 332 of the epitaxial structure 328, the first electrical type electrode layer 322, the second electrical type electrode layer 346 and insulating layer 326, thus substantially finishing the fabrication of the LED device 300b, as shown in FIG. 5B.

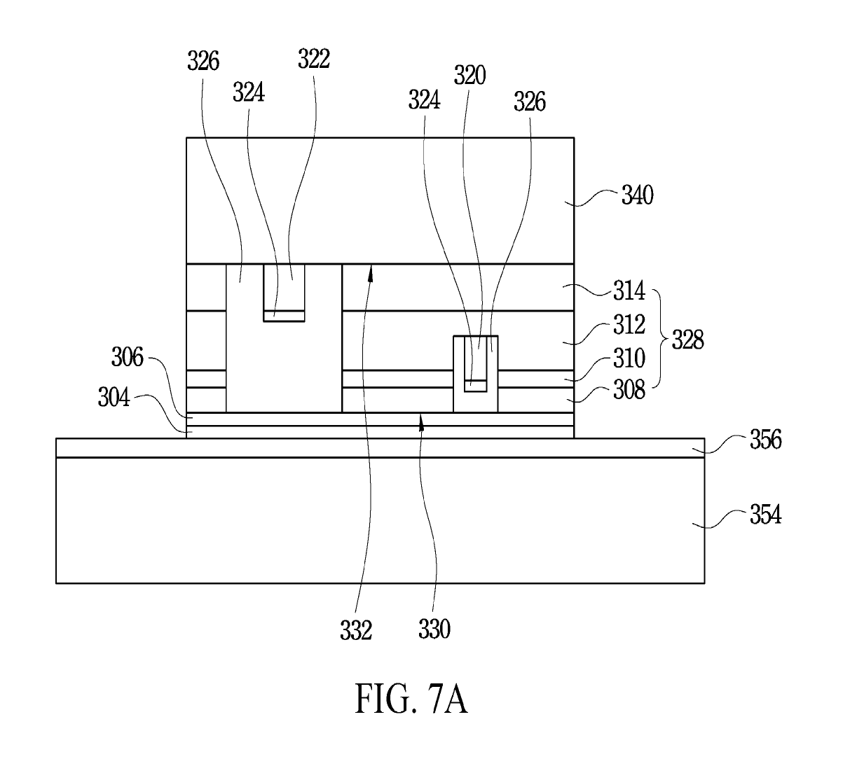

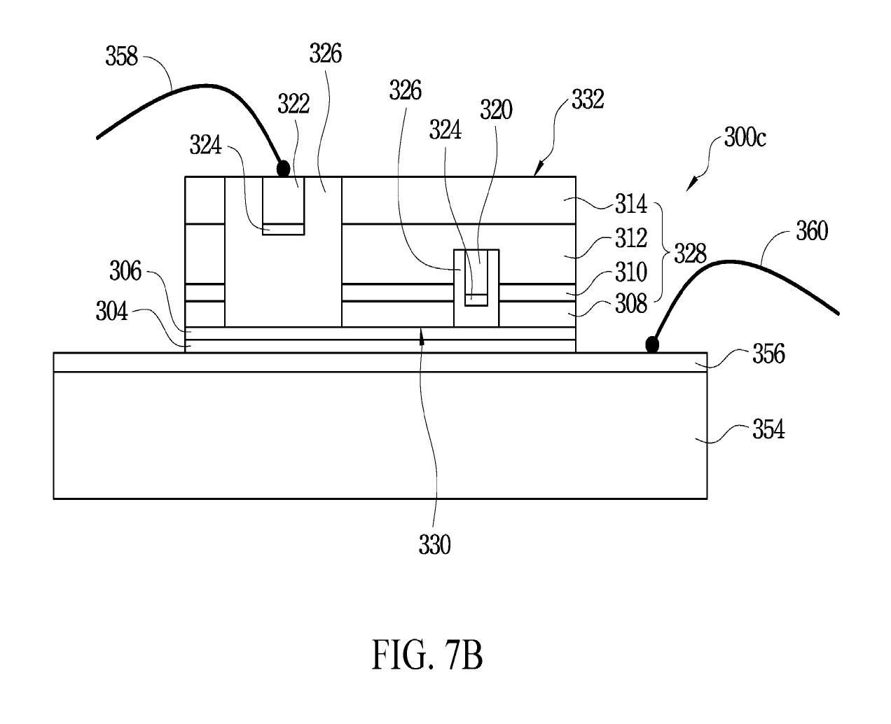

FIG. 7A and FIG. 7B are cross-sectional views of processes of an LED device according to a third embodiment of the present invention. In this embodiment, when the LED device 300c as shown in FIG. 7B is fabricated, similar to the description of the above embodiment with reference to FIG. 4A to FIG. 4D, a plurality of the epitaxial chips as shown in FIG. 4D may be formed on the wafer. Then, the epitaxial chips formed on the wafer are cut and separated.

Afterwards, a substrate 354 is provided. The substrate 354 may be for example a package substrate, a highly thermally conductive substrate or a package frame. Then, for example, a deposition process is employed to form the bonding layer 356 covering the surface of the substrate 354. The material of the bonding layer 356 may be a conductive material, e.g. Au, AuSn or In. In one embodiment, the bonding layer 356 may be used as the second electrical type electrode layer of the LED device 300c. In another embodiment, a second electrical type electrode layer may be additionally disposed between the second electrical type contact layer 306 and bonding layer 304 of the epitaxial chip. As shown in FIG. 7A, the bonding layer 304 on the cut epitaxial chip and the bonding layer 356 on the substrate 354 are used to fix the epitaxial chip to the substrate 354. In this embodiment, the size of the substrate 354 normally is greater than the size of the epitaxial chip.

After the epitaxial chip and the substrate 354 are bonded, for example, a laser lift-off or grinding process is employed to remove the epitaxial substrate 340, thus exposing the non-doped semiconductor layer 314 and the first electrical type electrode layer 322 of the epitaxial structure 328. Then, as shown in FIG. 7B, conductive leads 358 and 360 are formed to respectively connect the first electrical type electrode layer 322 and an electrode of an external circuit, and the bonding layer 356 and another electrode of the external circuit, thus finishing the fabrication of the LED device 300c. The two electrodes of the external circuit have different electrical type, and the electrical type of the two electrodes match the electrical type of the electrode layer of the bonded LED device 300c. For instance, when the first electrical type electrode layer 322 is n-type and the second electrical type electrode layer is p-type, the electrode type of the external circuit connected to the first electrical type electrode layer 322 is an n pole, and the electrode type of the external circuit connected to the bonding layer 356 is an p pole.

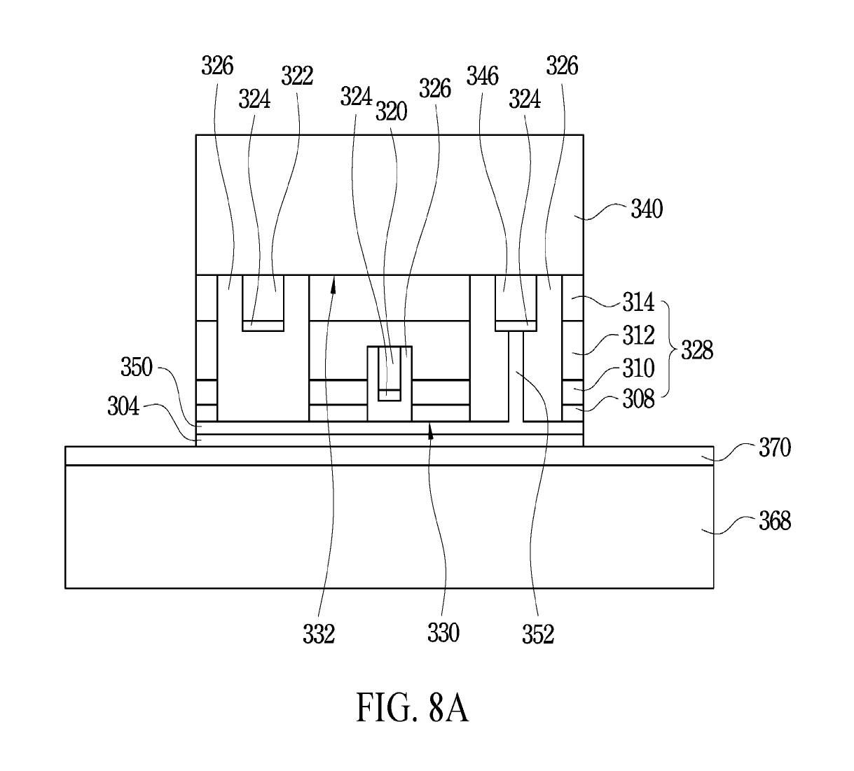

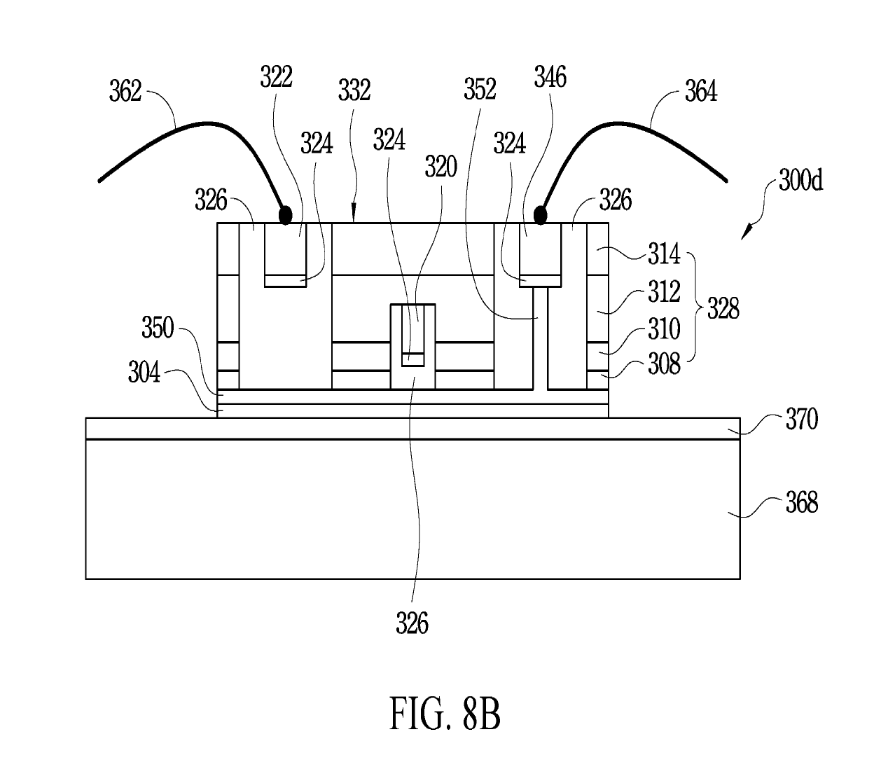

FIG. 8A and FIG. 8B are cross-sectional views of processes of an LED device according to a fourth embodiment of the present invention. In this embodiment, when the LED device 300d as shown in FIG. 8B is fabricated, same as the description of the embodiment with reference to FIG. 6A to FIG. 6D, a plurality of the epitaxial chips as shown in FIG. 6D may be formed on the wafer. Then, the epitaxial chips formed on the wafer are cut and separated.

Afterwards, a substrate 368 is provided. The substrate 368 may be for example a package substrate, a highly thermally conductive substrate or a package frame. Then, for example, a deposition process is employed to form a bonding layer 370 covering the surface of the substrate 368. The material of the bonding layer 370 is a conductive material, e.g. Au, AuSn or In. As shown in FIG. 8A, the bonding layer 304 on the cut epitaxial chip and the bonding layer 370 on the substrate 368 are used to fix the epitaxial chip on the substrate 368. In this embodiment, the size of the substrate 368 normally is greater than the size of the epitaxial chip.

Afterwards, for example, a laser lift-off or grinding process is employed to remove the epitaxial substrate 340, thus exposing the non-doped semiconductor layer 314, the first electrical type electrode layer 322 and the second electrical type electrode layer 346 of the epitaxial structure 328. Then, as shown in FIG. 8B, conductive leads 362 and 364 are formed to respectively connect the first electrical type electrode layer 322 and an electrode of an external circuit, and the second electrical type electrode layer 346 and another electrode of the external circuit, thus finishing the fabrication of the LED device 300d. The two electrodes of the external circuit have different electrical type.

When the LED devices 300c and 300d are fabricated, as the cut LED chip is disposed on the package substrate or the frame, in the follow-up processes, the exhaust passage is not required to be additionally fabricated for ventilation of a gas generated in the process of removing the growth substrate by laser lift-off. Therefore, the two embodiments when employed may increase the utilization rate of light-emitting area of the LED chip.

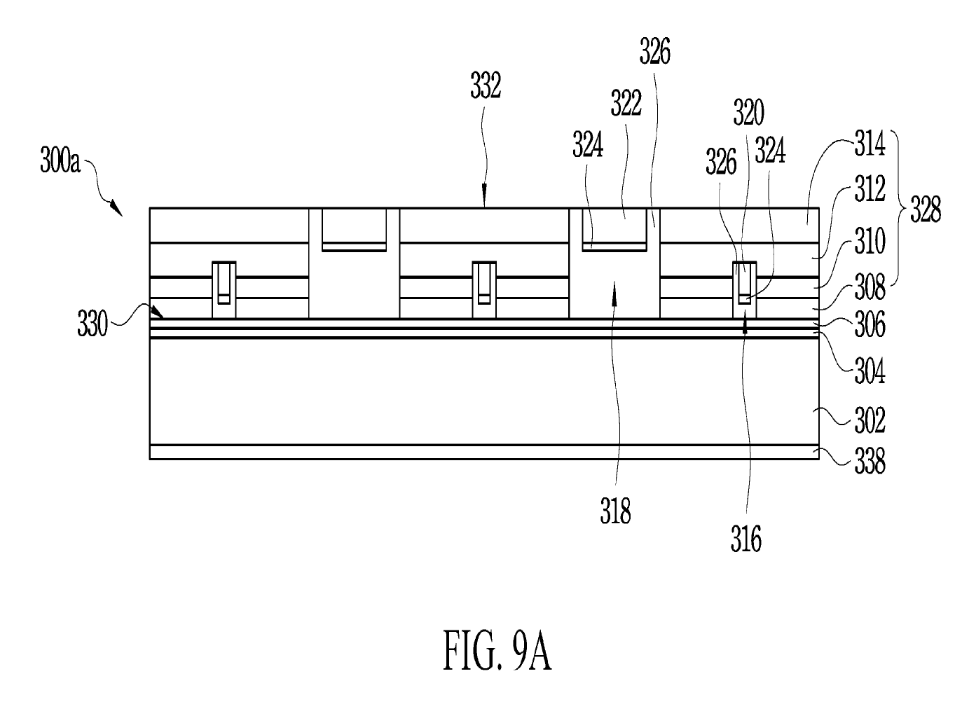

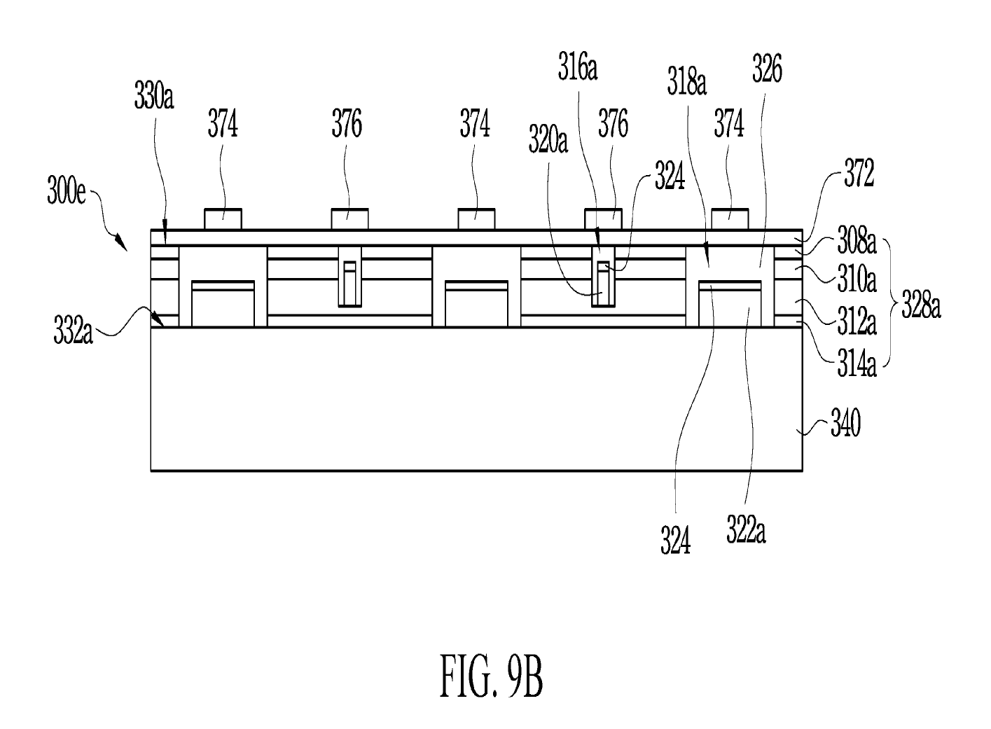

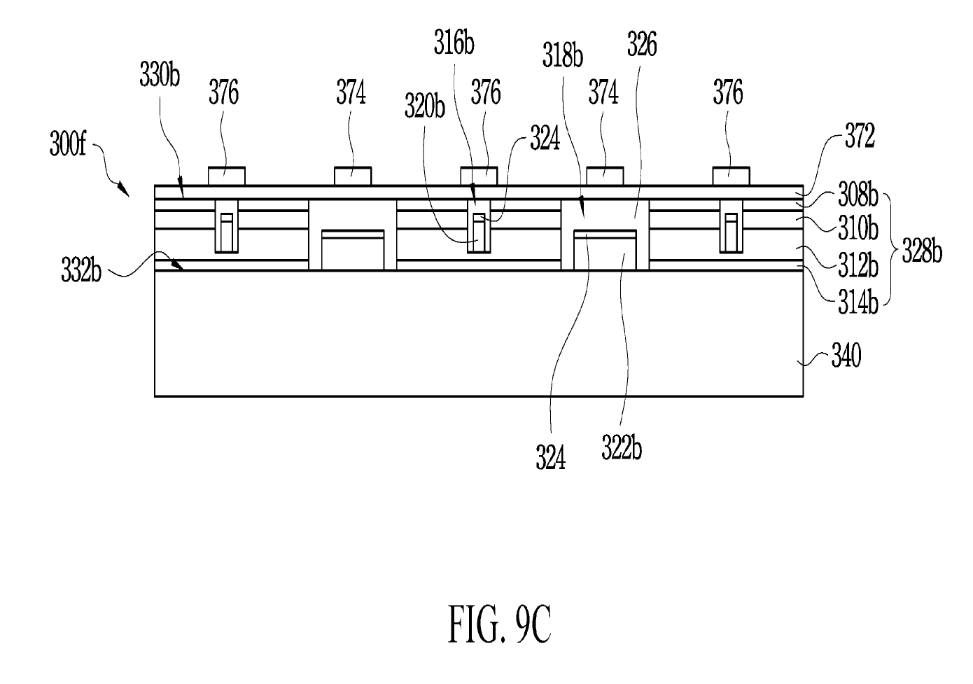

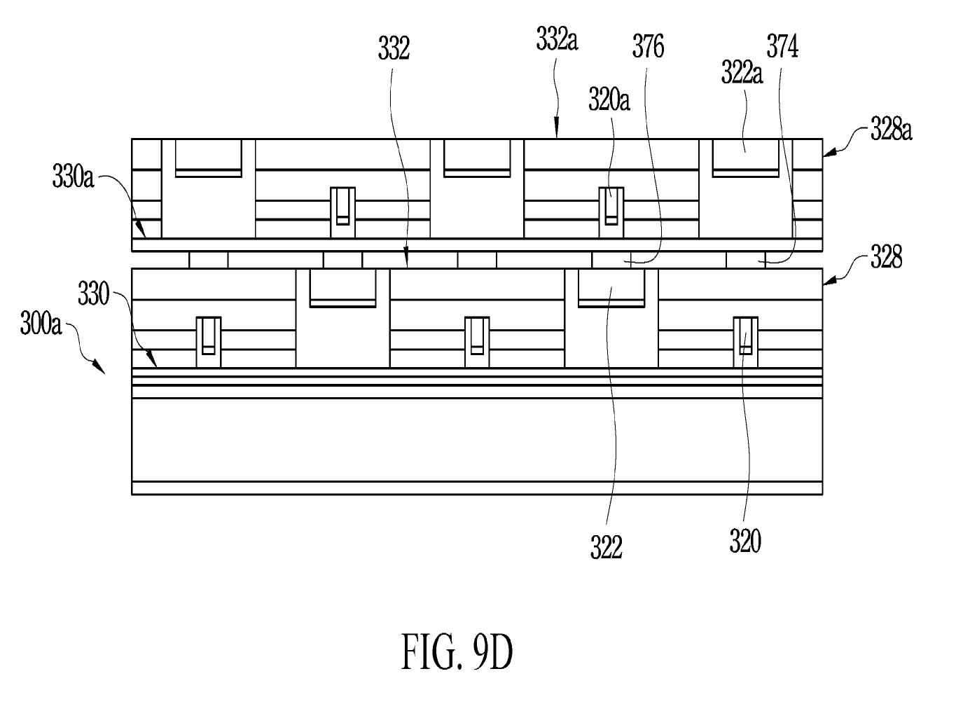

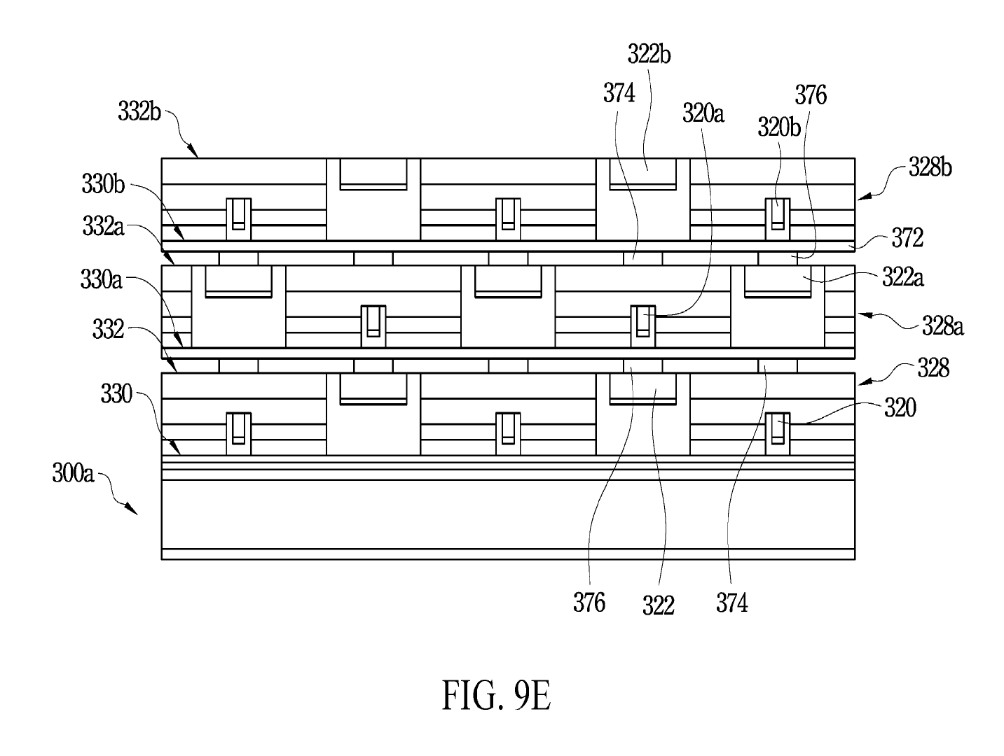

In the present invention, the LED chips having different light-emitting wavelengths may be combined together by stacking, thus forming an LED device that provides blended light. FIG. 9A to FIG. 9E are cross-sectional views of processes of an LED device according to a fifth embodiment of the present invention. In this embodiment, the LED device 300a in the first embodiment is firstly fabricated, as shown in FIG. 9A. In the LED device 300a shown in FIG. 9A, the fabrication of the light enhancement layer 366 is omitted. The LED device 300a may have a first light-emitting wavelength.

Then, as shown in FIG. 9B, an LED device 300e is fabricated. The structure of the LED device 300e is similar to the structure in FIG. 4C. The difference between two structures lies in that: the LED device 300e further includes a transparent conductive layer 372 covering a surface 330a of a light-emitting epitaxial structure 328a; and the LED device 300e further includes a plurality of bonding pads 374 and 376 respectively located on the transparent conductive layer 372 above a first electrical type electrode layer 322a and a first electrical type conductive branch 320a.

The LED device 300e may have a second light-emitting wavelength. The second light-emitting wavelength may be different from the first light-emitting wavelength. In one embodiment, the material of the transparent conductive layer 372 may be for example ITO, ZnO or NiAu alloy. The material of the bonding pads 374 and 376 may include for example In, Sn, AuSn alloy or AgSnCu alloy.

In the LED device 300e, the epitaxial structure 328a includes a non-doped semiconductor layer 314a, a first electrical type semiconductor layer 312a, an active layer 310a and a second electrical type semiconductor layer 308a sequentially stacked on the substrate 340. The epitaxial structure 328a includes two surfaces 330a and 332a located on two opposite sides thereof. The epitaxial structure 328a further has at least one groove 316a and at least one groove 318a. The groove 316a extends from the second electrical type semiconductor layer 308a to the first electrical type semiconductor layer 312a, that is, the groove 316a extends from the surface 330a of the epitaxial structure 328a to the first electrical type semiconductor layer 312a via the active layer 310a. And, the bottom of the groove 316a exposes a part of the first electrical type semiconductor layer 312a. The groove 318a penetrates the epitaxial structure 328a from the second electrical type semiconductor layer 308a, that is, the groove 318a extends from the surface 330a of the epitaxial structure 328a to the surface 332a.

Moreover, the first electrical type electrode layer 322a is disposed on groove 318a and coplanar with the surface 332a of the epitaxial structure 328a. The first electrical type conductive branch 320a is disposed on the first electrical type semiconductor layer 312a exposed by the groove 316a of the epitaxial structure 328a. Similar to the structure in FIG. 3C, the first electrical type electrode layer 322a and the first electrical type conductive branch 320a are connected.

Meanwhile, as shown in FIG. 9C, an LED device 300f is fabricated. The structure of the LED device 300f is identical to that of the LED device 300e. However, the LED device 300f may have a third light-emitting wavelength, and the third light-emitting wavelength may be different from the first light-emitting wavelength and the second light-emitting wavelength.

Likewise, in the LED device 300f, an epitaxial structure 328b includes a non-doped semiconductor layer 314b, a first electrical type semiconductor layer 312b, an active layer 310b and a second electrical type semiconductor layer 308b sequentially stacked on the substrate 340. The epitaxial structure 328b includes two surfaces 330b and 332b located on two opposite sides thereof. The epitaxial structure 328b further has at least one groove 316b and at least one groove 318b. The groove 316b extends from the second electrical type semiconductor layer 308b to the first electrical type semiconductor layer 312b, that is the groove 316b extends from the surface 330b of the epitaxial structure 328b to the first electrical type semiconductor layer 312b via the active layer 310b. And, the bottom of the groove 316b exposes a part of the first electrical type semiconductor layer 312b. The groove 318b penetrates the epitaxial structure 328b from the second electrical type semiconductor layer 308b, that is the groove 318b extends from the surface 330b of the epitaxial structure 328b to the surface 332b.

Moreover, the first electrical type electrode layer 322b is disposed in the groove 318b and coplanar with the surface 332b of the epitaxial structure 328b. The first electrical type conductive branch 320b is disposed on the first electrical type semiconductor layer 312b exposed by the groove 316b of the epitaxial structure 328b. Similar to the structure shown in FIG. 3C, the first electrical type electrode layer 322b and the first electrical type conductive branch 320b are connected.

Then, the epitaxial chips of the LED devices 300e and 300f are cut. Afterwards, by mean of the bonding pads 374 and 376 of the LED device 300e facing the epitaxial structure 328, the LED device 300e is adhered to the LED device 300a. Then, as shown in FIG. 9D, the substrate 340 of the LED device 300e is removed to expose the surface 332a of the epitaxial structure 328a.

After the LED device 300e is disposed on the LED device 300a, the bonding pads 374 and 376 of the LED device 300e are sandwiched between the transparent conductive layer 372 and the epitaxial structure 328 of the LED device 300e. That is to say, the transparent conductive layer 372 of the LED device 300e is located above the surface 332 of the epitaxial structure 328. In one embodiment, as shown in FIG. 9D, the bonding pad 374 of the LED device 300e passes through a connection lead in space between the first electrical type electrode layer 322a and first electrical type conductive branch 320 of the LED device 300a. And, the bonding pad 376 of the LED device 300e passes through a connection lead in space between the first electrical type conductive branch 320a and the first electrical type electrode layer 322 of the LED device 300a.

Then, likewise, by mean of the bonding pads 374 and 376 of the LED device 300f facing the epitaxial structure 328a, the LED device 300f is adhered to the LED device 300e. Afterwards, as shown in FIG. 9E, the substrate 340 of the LED device 300f is removed to expose the surface 332b of the epitaxial structure 328b. Till now, the fabrication of the LED chip having three light-emitting wavelengths, i.e. the LED device formed by the LED device 300a, the epitaxial structures 328a of the LED device 300e and the epitaxial structure 328b of LED device 300f, is substantially finished.

After the LED device 300f is disposed on the epitaxial structure 328a, the bonding pads 374 and 376 of the LED device 300f are sandwiched between the transparent conductive layer 372 of the LED device 300f and epitaxial structure 328a. That is to say, the transparent conductive layer 372 of the LED device 300f is located above the surface 332a of the epitaxial structure 328a. In one embodiment, as shown in FIG. 9E, the bonding pad 374 of the LED device 300f passes through a connection lead in space between the first electrical type electrode layer 322b and the first electrical type conductive branch 320a. The bonding pad 376 of the LED device 300f passes through a connection lead in space between the first electrical type conductive branch 320b and the first electrical type electrode layer 322a.

In the exemplary embodiment of the fifth embodiment, the light-emitting wavelength of the epitaxial structure 328 of the LED device 300a in a lower position is short, the light-emitting wavelength of the epitaxial structure 328a in a middle position is longer than that of the epitaxial structure 328, and the light-emitting wavelength of the epitaxial structure 328b in an upper position is longer than that of the epitaxial structure 328a. With the arrangement, the light with short wavelengths emitted by the epitaxial structure 328 and/or the epitaxial structure 328a in the lower position may be used to excite the epitaxial structure 328a and/or the epitaxial structure 328b having longer wavelengths in the upper position.

According to the above embodiments of the present invention, the advantage of the present invention is that the conductive branch of the LED device of the present invention is disposed in the epitaxial structure, so the proportion of the light absorbed by the conductive branch may be reduced.

According to the above embodiments of the present invention, another advantage of the present invention is that the first electrical type electrode pad and the first electrical type conductive branch are disposed on the Ga-face of the first electrical type semiconductor layer in the method for manufacturing the LED device of the present invention, so the thermal stability of first electrical type electrode pad and the first electrical type conductive branch is improved.

According to the above embodiments of the present invention, still another advantage of the present invention is that the second electrical type contact layer that also provides a reflective function of the LED device of the present invention is fabricated after the annealing process of the first electrical type electrode pad and the first electrical type conductive branch, so the reflectivity of the second electrical type contact layer can be effectively controlled.

According to the above embodiments of the present invention, yet another advantage of the present invention is that in the method for manufacturing the LED device of the present invention, the cut LED chip may be directly fixed on the package substrate or the conductive lead frame, and then the growth substrate is removed, thus finishing the fabrication of the LED device. Therefore, after the growth substrate is removed, the lithographic process is not required.

According to the above embodiments of the present invention, still another advantage of the present invention is that in the method for manufacturing the LED device of the present invention, after the cut LED chip is disposed on the package substrate or the frame, the exhaust passage is not required to be additionally fabricated for ventilation of a gas generated in the process of removing the growth substrate by laser lift-off. Therefore, the utilization rate of the light-emitting area of the LED chip can be increased.

According to the above embodiments of the present invention, still another advantage of the present invention is that the LED chips having different light-emitting wavelengths may be successfully combined together by stacking, thus forming the LED device with the blended light. Therefore, the diversity and applicability of the high LED device are improved.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims and the foregoing description and the exemplary embodiments described therein as a whole.

What is claimed is:

1. A light-emitting diode (LED) device, comprising:
a substrate, having a first surface and a second surface opposite to each other;
a first bonding layer, disposed on the first surface;
a first epitaxial structure, having a third surface and a fourth surface opposite to each other and comprising a first groove and a second groove, wherein the first epitaxial structure comprises a second electrical type semiconductor layer, an active layer and a first electrical type semiconductor layer sequentially stacked on the first bonding layer, and the first groove extends from the fourth surface to the first electrical type semiconductor layer via the active layer, the second groove extends from the fourth surface to the third surface, and the first electrical type semiconductor layer and the second electrical type semiconductor layer have different electrical type;
a first electrical type conductive branch, disposed on the first electrical type semiconductor layer in the first groove;
a first electrical type electrode layer, disposed in the second groove, coplanar with the third surface and connected to the first electrical type conductive branch;
an insulating layer, filled in the first groove and the second groove; and
a second electrical type electrode layer, electrically connected to the second type electrical semiconductor layer.

2. The LED device according to claim 1, wherein the second electrical type electrode layer is disposed on the second surface of the substrate, and the substrate is a conductive substrate.

3. The LED device according to claim 1, wherein:
the first epitaxial structure further comprises a third groove extending from the fourth surface to the third surface, and the insulating layer is further filled in the third groove;
the second electrical type electrode layer is disposed in the third groove and coplanar with the third surface; and
the LED device further comprises a conductive layer electrically connected to the second electrical type electrode layer and the second electrical type semiconductor layer.

4. The LED device according to claim 3, further comprising:
a first conductive lead, electrically connected to the first electrical type electrode layer and a first electrode of an external power supply; and
a second conductive lead, electrically connected to the second electrical type electrode layer and a second electrode of the external power supply.

5. The LED device according to claim 1, further comprising:
a second bonding layer, disposed between the substrate and the first bonding layer;
a first conductive lead, electrically connected to the first electrical type electrode layer and a first electrode of an external power supply; and
a second conductive lead, electrically connected to the second bonding layer and a second electrode of the external power supply.

6. The LED device according to claim 1, further comprising a reflective layer disposed on the first electrical type electrode layer and the first electrical type conductive branch.

7. The LED device according to claim 1, further comprising a second electrical type contact layer disposed between the first bonding layer and the second electrical type semiconductor layer.

8. The LED device according to claim 1, further comprising a non-doped semiconductor layer disposed on the first electrical type semiconductor layer, wherein the third surface of the first epitaxial structure is one surface of the non-doped semiconductor layer.

9. The LED device according to claim 1, further comprising a light enhancement layer disposed on a non-doped semiconductor layer, where a refractive index of the light enhancement layer is greater than the refractive index of air but is smaller than the refractive index of the non-doped semiconductor layer.

10. The LED device according to claim 1, further comprising:
a first transparent conductive layer, disposed on the third surface;
a second epitaxial structure, having a fifth surface and a sixth surface opposite to each other and comprising a third groove and a fourth groove, wherein the second epitaxial structure comprises another second electrical type semiconductor layer, another active layer and another first electrical type semiconductor layer sequentially stacked on the first transparent conductive layer, the third groove extends from the sixth surface to the another first electrical type semiconductor layer via the another active layer, and the fourth groove extends from the sixth surface to the fifth surface;
a plurality of first bonding pads, bonded between the first transparent conductive layer and the first epitaxial structure;
another first electrical type conductive branch, disposed on the another first electrical type semiconductor layer in the third groove;
another first electrical type electrode layer, disposed in the fourth groove, coplanar with the fifth surface, and connected to the another first electrical type conductive branch; and
another insulating layer, filled in the third groove and the fourth groove.

11. The LED device according to claim 10, wherein one of the first bonding pads passes through a connection lead in space between the another first electrical type electrode layer and the first electrical type conductive branch, and another one of the first bonding pads passes through a connection lead in space between the another first electrical type conductive branch and the first electrical type semiconductor layer.

12. The LED device according to claim 10, further comprising:
a second transparent conductive layer, disposed on the fifth surface;
a third epitaxial structure, having a seventh surface and an eighth surface opposite to each other and comprising a fifth groove and a sixth groove, wherein the third epitaxial structure comprises still another second electrical type semiconductor layer, still another active layer and still another first electrical type semiconductor layer sequentially stacked on the second transparent conductive layer, the fifth groove extends from the eighth surface to the still another first electrical type semiconductor layer via the still another active layer, and the sixth groove extends from the eighth surface to the seventh surface;
a plurality of second bonding pads, bonded between the second transparent conductive layer and the second epitaxial structure;
still another first electrical type conductive branch, disposed on the still another first electrical type semiconductor layer in the fifth groove;
still another first electrical type electrode layer, disposed in the sixth groove, coplanar with the seventh surface and connected to the still another first electrical type conductive branch; and
still another insulating layer, filled in the fifth groove and the sixth groove.

13. The LED device according to claim 12, wherein one of the second bonding pads passes through a connection lead in space between the still another first electrical type electrode layer and the another first electrical type conductive branch, and another one of the second bonding pads passes through a connection lead in space between the still another first electrical type conductive branch and the another first electrical type semiconductor layer.

14. A method for manufacturing a light-emitting diode (LED) device, comprising:
forming a first epitaxial structure on a first substrate, wherein the first epitaxial structure comprises a first electrical type semiconductor layer, an active layer and a second electrical type semiconductor layer sequentially stacked on the first substrate, and the first epitaxial structure comprises a first groove and a second groove, the first groove and the second groove respectively extend from the second electrical type semiconductor layer to the first electrical type semiconductor layer and the first substrate;
forming a first electrical type conductive branch and a first electrical type electrode layer respectively on the first electrical type semiconductor layer in the first groove and on the first substrate in the second groove;
forming an insulating layer filled in the first groove and the second groove;
forming a first bonding layer on the second electrical type semiconductor layer and the insulating layer;
bonding a second substrate to the first bonding layer; and
removing the first substrate.

15. The method for manufacturing an LED device according to claim 14, further comprising a step of forming a second electrical type electrode layer, wherein the step of forming the second electrical type electrode layer is performed after the step of removing the first substrate, the second electrical type electrode layer and the first bonding layer are respectively located on two opposite sides of the second substrate, and the second substrate is a conductive substrate.

16. The method for manufacturing an LED device according to claim 14, wherein:
the first epitaxial structure further comprises a third groove extending from the second electrical type semiconductor layer to the first substrate;
the method for manufacturing the LED device further comprises forming a second electrical type electrode layer, the step of forming the second electrical type electrode layer comprises forming the second electrical type electrode layer on the first substrate in the third groove before the step of forming the insulating layer;
the step of forming the insulating layer comprises filling the insulating layer in the third groove, and forming an opening that exposes a part of the second electrical type electrode layer in the insulating layer of the third groove; and
the method for manufacturing the LED device further comprises forming a conductive layer covering the insulating layer and filling up the opening after the step of forming the insulating layer.

17. The method for manufacturing an LED device according to claim 16, after the step of removing the first substrate, further comprising:
forming a first conductive lead electrically connected to the first electrical type electrode layer and a first electrode of an external power supply; and
forming a second conductive lead electrically connected to the second electrical type electrode layer and a second electrode of the external power supply.

18. The method for manufacturing an LED device according to claim 14, wherein the step of bonding the second substrate to the first bonding layer comprises:
forming a second bonding layer on the second substrate; and
bonding the first epitaxial structure to the second substrate by using the first bonding layer and the second bonding layer.

19. The method for manufacturing an LED device according to claim 18, after the step of removing the first substrate, further comprising:
forming a first conductive lead electrically connected to the first electrical type electrode layer and a first electrode of an external power supply; and
forming a second conductive lead electrically connected to the second bonding layer and a second electrode of the external power supply.

20. The method for manufacturing an LED device according to claim 14, further comprising:
forming a second epitaxial structure, wherein the second epitaxial structure has a first surface and a second surface opposite to each other, the second epitaxial structure comprises another second electrical type semiconductor layer, another active layer and another first electrical type semiconductor layer sequentially stacked, the second epitaxial structure comprises a third groove and a fourth groove, the third groove and the fourth groove respectively extend from the second surface to the another first electrical type semiconductor layer and the first surface via the another active layer;
forming another first electrical type conductive branch on the another first electrical type semiconductor layer in the third groove;
forming another first electrical type electrode layer in the fourth groove, wherein the another first electrical type electrode layer is coplanar with the first surface, and connected to the another first electrical type conductive branch;
filling another insulating layer in the third groove and the fourth groove;
forming a first transparent conductive layer on the second surface;
forming a plurality of first bonding pads on the first transparent conductive layer; and
bonding the first transparent conductive layer and the first epitaxial structure by using the first bonding pads.

21. The method for manufacturing an LED device according to claim 20, further comprising:
forming a third epitaxial structure, wherein the third epitaxial structure has a third surface and a fourth surface opposite to each other, the third epitaxial structure comprises still another second electrical type semiconductor layer, still another active layer and still another first electrical type semiconductor layer sequentially stacked, the third epitaxial structure comprises a fifth groove and a sixth groove, the fifth groove and the sixth groove respectively extend from the fourth surface to the still another first electrical type semiconductor layer and the third surface via the still another active layer;
forming still another first electrical type conductive branch on the still another first electrical type semiconductor layer in the fifth groove;
forming still another first electrical type electrode layer in the sixth groove, wherein the still another first electrical type electrode layer is coplanar with the third surface, and connected to the still another first electrical type conductive branch;
filling still another insulating layer in the fifth groove and the sixth groove;
forming a second transparent conductive layer on the fourth surface;
forming a plurality of second bonding pads on the second transparent conductive layer; and
bonding the second transparent conductive layer and the second epitaxial structure by using the second bonding pads.
